(19) United States
(12) Patent Application Publication
(10) Pub. No.: US 2004/0195966 A1
(43) Pub. Date: Oct. 7, 2004

(54) Method of providing a layer including a metal or silicon or germanium and oxygen on a surface

(76) Inventors: Natasha M J Conway, Cambridge (GB); Alan Mosley, Berkhamsted (GB)

Correspondence Address: James P Zeller, Marshall Gerstein & Borun, 6300 Sears Tower, 233 South Wecker Drive, Chicago, IL, 60606-6357, US

(21) Appl. No.: 10/477,336

(22) PCT Filed: May 13, 2002
(86) PCT No.: PCT/GB02/02181

(30) Foreign Application Priority Data
May 14, 2001 (GB) 0111751.4
Apr. 10, 2002 (GB) 0208230.3

(51) Int. Cl. H05B 33/02; C23C 16/06

(52) U.S. Cl. 313/509; 427/255.31; 427/66

(57) ABSTRACT

A method of providing a layer including a metal or silicon or germanium and oxygen on a surface, the method including the steps of forming an adsorbed layer less than 12 monolayers thick on the surface by exposing it to a liquid or vapor containing metal-, silicon-, or germanium-containing organic molecules, and treating this layer by exposure to a glow discharge in an oxygen containing gas, thereby converting the adsorbed layer to a layer including silicon (or germanium) and oxygen.

This invention relates to a method of providing a layer including a metal or silicon or germanium and oxygen on a surface.

Optical devices such as displays and backlights for liquid crystal displays having organic electroluminescent diodes (OLEDs) are being widely developed. A key advantage of OLEDs is their luminous efficiency, which is often measured as an external quantum efficiency quoted in candelas per amp and/or a luminance efficacy quoted in lumens per watt. The luminance efficacy of an OLED is particularly important since it determines the power consumed by the OLED when emitting light and hence the battery life of a portable device.

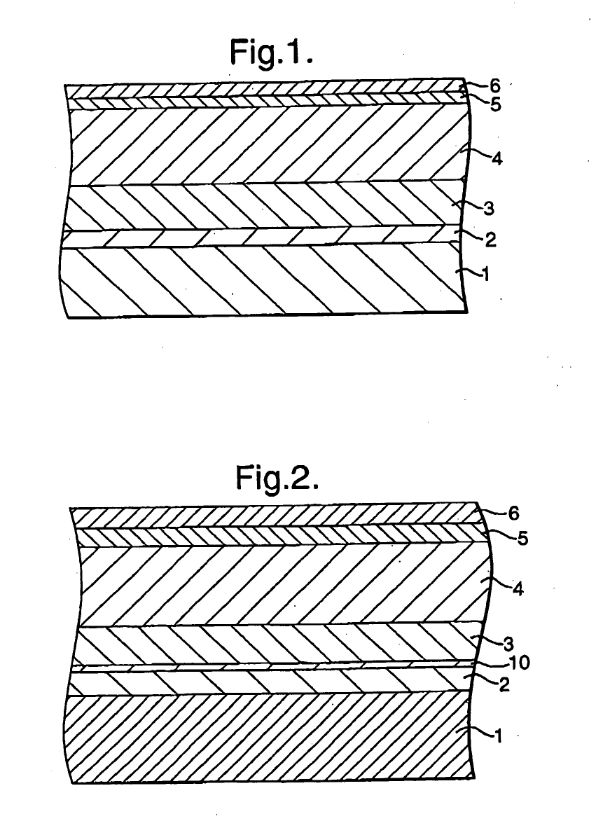

The general structure of OLEDs (shown in FIG. 1) consists of a glass substrate (1) whose inner surface is coated with a transparent conductor (2) such as indium tin oxide, on top of which are sequentially formed layers of organic and/or organometallic chemicals that provide charge injection (3), charge carriage and/or light emission (4) followed by one or more layers (typically a very electropositive metal (5) capped with a layer of aluminium (6)) that form the second electrode of the OLED.

A very thin dielectric layer, (for example less than 1 nm thick) such as silicon dioxide, placed adjacent to the indium tin oxide layer can enhance the injection of charge from the indium tin oxide, thereby improving the luminous efficiency of the device. However it is very difficult to deposit a thin dielectric layer uniformly, especially over the large areas, for example 400×400 mm², of the glass substrates used in the manufacture of OLEDs. When such depositions are attempted using conventional means, such as sputtering or electron beam evaporation, it is found that some areas will be coated with a dielectric layer whose thickness is greater than 1 nm, while other areas will have a dielectric layer thickness of less 1 nm. This variation in the thickness of the dielectric layer will cause a variation in the voltage required to generate light, the voltage increasing with the increasing thickness of the dielectric layer. As the voltage increases, the luminance efficacy will decrease, thereby reducing the battery life of portable equipment using the OLED. Because the thickness of the dielectric layer is small, even a small change, e.g. 0.2 nm, will cause a large change in the performance of the OLED.

According to a first aspect of the present invention there is provided a method of providing a layer including silicon (or germanium) and oxygen on a surface as claimed in claims 1-7. According to a second aspect of the invention there is provided an electroluminescent device incorporating such a layer as claimed in claims 8 and 9.

Embodiments of the invention will now be described, with reference to the accompanying schematic drawings, in which:

FIG. 1 shows a cross-section of a conventional organic light emitting device,

FIG. 2 shows a cross-section of an organic light emitting device according to the present invention,

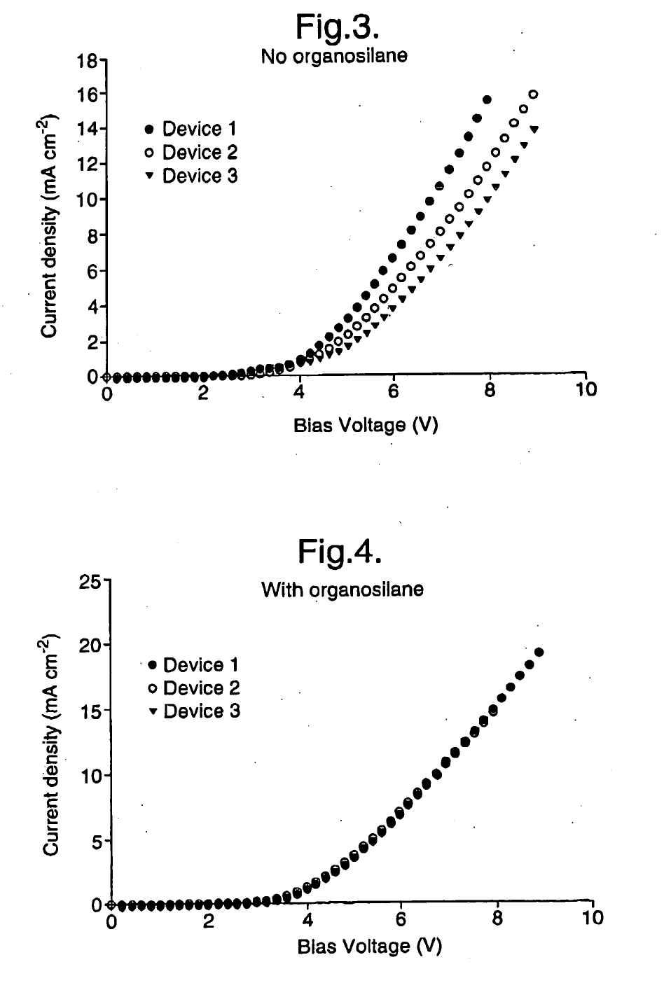

FIG. 3 shows the current-voltage characteristics of three conventional organic light emitting devices,

FIG. 4 shows the current-voltage characteristics of three organic light emitting devices according to the present invention,

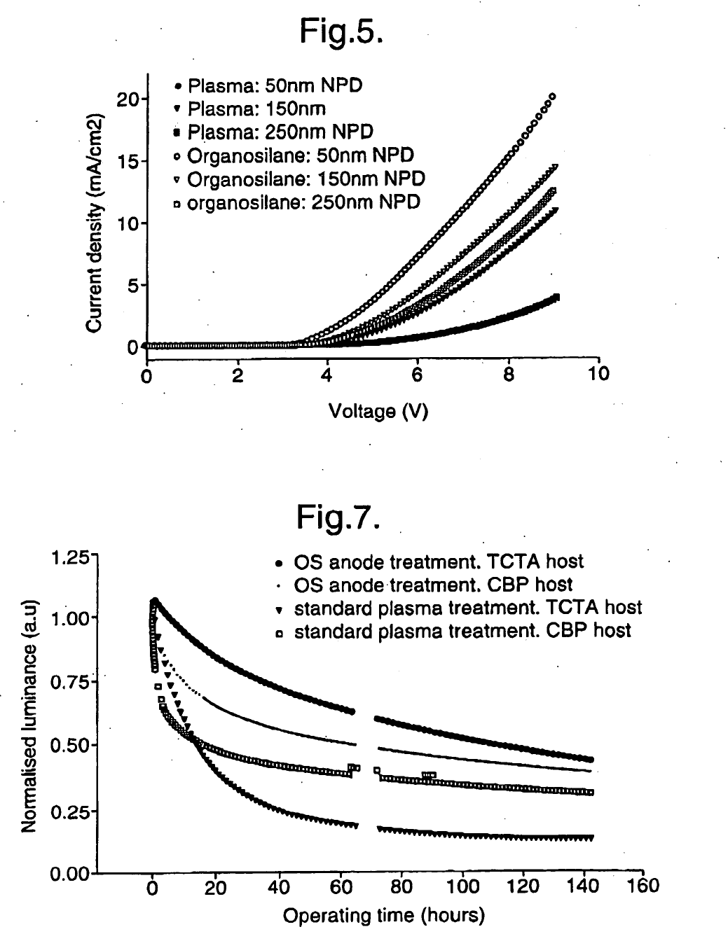

FIG. 5 shows current-voltage characteristics of three organosilane-treated and three plasma-treated devices with differing thickness of NPD,

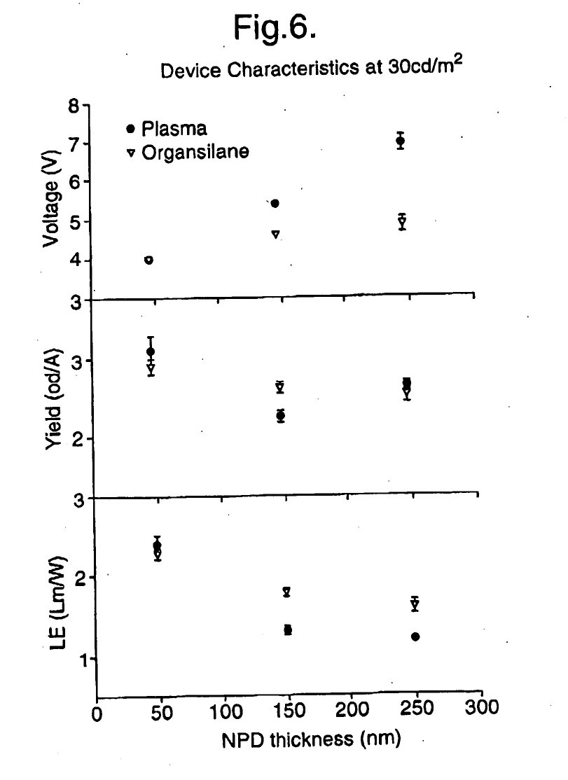

FIG. 6 shows the voltage, yield and luminous efficiency of an organosilane-treated and a plasma-treated device with increasing thickness of the NPD layer, and

FIG. 7 shows the lifetime characteristics of two organosilane-treated and two plasma-treated devices.

The present invention is able to provide very thin, uniform layers of a dielectric material on top of a transparent conductive metal oxide such as indium tin oxide. The thickness of the layer of dielectric material is less than 3 nm, preferably less than 2 nm and very preferably less than 1 nm. Using the present invention it has been possible to demonstrate increases in luminous efficacies from 1.5 to 2.3 lm/W.

This new technique involves the use of silicon or germanium containing organic materials such as organosilane materials, which are readily available because they are generally used as adhesion promoters. A typical organosiliane adhesion promoter is 3-aminopropyl-triethoxysilane, which is provided by Du Pont under the trade name VM651. Other materials, such as for example hexamethyl disiloxane, can be used as an alternative

The surface of the indium tin oxide is first exposed to an organosilane adhesion promoter in liquid or vapour form in the conventional manner for use as an adhesion promoter. This provides a very thin and uniform layer of an organosilane bonded to the ITO and glass surfaces through silicon-oxygen bonds. The organosilane layer also contains an organic group. In the case of VM651 this group would be the 3-aminopropyl group. A surface having such a layer is often termed “primed”

The “primed” substrate is subsequently treated, ie. in the absence of organosilane, with an oxidising medium, such as an oxygen plasma or glow discharge containing oxygen radicals. This oxidising medium adds oxygen to that part of the adsorbed layer to be oxidised, such that in this instance it will oxidise the organic moieties to volatile species, such as water and carbon dioxide, and leave a thin layer of silicon dioxide on the surface of the ITO. Hence this technique provides a ready means for producing a thin uniform layer of a dielectric material. This layer may contain other constituents such as hydrogen and carbon, such that the silicon oxide layer is not necessarily stoichiometric.

It is often stated that because of their chemical structure organosilane adhesion promoters produce a monolayer on suitable substrates. We have observed that this is not necessarily the case.

An example of the process described in more detail is presented next, and an example of a cross section of a device manufactured in accordance with the invention is shown in FIG. 2. Glass substrates (1) coated with a layer of Indium Tin Oxide (2)), which can be purchased from several suppliers, for example Applied Films, USA or Merck Display Technology, Taiwan, are cleaned and patterned using a standard detergent and photolithography processes.

After the final stage of the photolithography process, i.e. the removal of the photoresist, the substrates are cleaned in a detergent, thoroughly rinsed in deionised water, dried, and baked at 105° C. for 30 minutes. After cooling the, substrate is primed by spin-coated (2000 rpm for 30 seconds) with a solution of methanol (95 ml), water (5 ml) and 3-aminopropyl-triethoxysilane (3 drops), and then stored at 105° C. in a dry nitrogen ambient until required.

Immediately prior to the formation of the OLED device, the primed substrate is exposed to an oxygen plasma to form a thin layer (10) consisting of or including silicon and oxygen. By way of example, an Emitech K1050X plasma etcher operated at 100 Watts for two minutes provided an acceptable treatment. The substrate is then immediately transferred to a vacuum deposition system where, by way of example the following layers are deposited sequentially; 4,4-bis[N-(1-naphthyl)-N-phenyl-amino]diphenyl (NPD) (3) and tris (8-hydroxy-quinolato) aluminium (AlQ) (4), lithium fluoride (5), and aluminium (6) with thicknesses of 50, 50, 1.5 and 150 nm respectively. For comparison similar OLED devices were fabricated without the organosilane layer and with the organosilane layer but without the oxidation treatment of the organosilane. The external quantum efficiencies in cd/A and the luminous efficacy in lm/W were measured and are shown in Table 1 below.

TABLE 1

| Treatment | Lm/W | Cd/A |
|---|---|---|
| Organosilane with Oxidation | 2.2 | 2.8 |
| Organosilane without Oxidation | 0.7 | 3.1 |
| None | 1.3 | 3.2 |

The advantage of the oxidised organosilane layer is that it leads to the injection of an equivalent amount of charge at a lower voltage, thereby providing a higher luminous efficacy which will result in a longer battery life for a portable product having an OLED display or backlight.

Another advantage of the oxidised organosilane layer is that the reproducibility of the OLED device characteristics is better for devices which have the oxidised organosilane layer than for devices which do not have the layer. As an example, the current-voltage curves of three devices prepared without the oxidised organosilane layer are shown in FIG. 3, and curves for three devices having an oxidised organosilane layer are shown in FIG. 4; in both cases the structure of the devices used to give the characteristics was ITO/NPD/ALQ/LiF/Al.

There is significantly less spread in the current-voltage curves for devices made with the oxidised organosilane layer, even although in all other regards the devices were prepared in an identical way.

The effect of the thickness of the NPD layer (in the range 50 nm to 250 nm) is shown in FIG. 5 and FIG. 6 for organosilane-treated and standard plasma-treated ITO/NPD/AlQ/LiF/Al devices.

FIG. 5 shows the relationship between current density and voltage with varying NPD thickness for organosilane-treated and standard plasma-treated devices. The current drops as the NPD thickness increases but the drop is more significant for the plasma-only devices. The reduced sensitivity to NPD thickness shown by organosilane-treated devices in FIG. 5 is also reflected in FIG. 6, where it is shown that the voltage required for 30 cd/m² increases more significantly with NFD thickness for the standard plasma-treated devices compared with organosilane-treated devices. This suggests that the organosilane layer improves the efficiency of hole injection. The higher voltage requirement at high NPD thickness for the standard plasma-treated devices compared with organosilane-treated devices is also shown in the lower luminous efficiency results.

A further comparative example of the organosilane process is provided using an OLED in which the light-emitting layer comprises a host doped with an iridium dendrimer material. Specifically, the emission layer comprises of a blend of either 20 wt % first generation iridiurn dendrimer (G1IrDen) in a 4,4¹-N,N¹-dicarbazole-biphenyl (CBP) host or 13 wt % G1IrDen in a 4,4¹, 4¹¹-tri(N-carbazoly)triphenylamine (TCTA) host. Solutions of the blends are made using chloroform and toluene, respectively, and then spin-coated onto either organosilane-treated or standard plasma-treated ITO substrates. The electron-transport layer (50 nm of 2,2¹,2¹¹-(1,3,-phenylene)tris[1-phenyl-1H-benzimidazoly] (TPBI) and cathode layers (LiF/Al) are subsequently deposited by thermal evaporation. FIG. 7 shows the improvement in the lifetimes of the organosilane-treated devices compared with the standard plasma-treated devices for both a CBP and TCTA host material.

It is envisaged that in addition to the organic moieties used in the light-emitting layers of the above examples, the organosilane layer provided in accordance with the present method may be used with a polymeric light-emitting layer. Preferred electroluminescent devices including such polymers are ITO/TOS/PFO/Ca/Al (a blue emitter) and ITO/TOS/(PFO+5% BT)/Ca/Al (yellow emitter) wherein:

TOS is the treated organosilane layer;

PFO is Poly[9,9-di-(2-ethylhexyl)fluorenyl-2,7′-diyl]; and

BT is Poly[(9,9-di-n-octylfluorenyl-2,7′-diyl)-co-(1,4-benzo(2,1′,3-thiadazole))]

Suitable organosilanes are carbon-containing compounds with the formula (X)₃SiR, where X is a hydrolysable group such as OEt, OMe, or Cl, and R is an organic fragment such as an alkyl chain which optionally contains a functional group such as NH₂. R has to oxidise to volatile species and so R can contain the following elements C, H, N, O, and S. As is known, organosilanes with this formula can chemisorb to ITO forming a monolayer bonded via 0-Si bonds. Depending on the conditions used, multiple layers may also form on top of the initial layer, but this is not necessarily disadvantageous. The layer is preferably thinner than 12 monolayers, however.

Siloxanes can also be used. These have the formula:

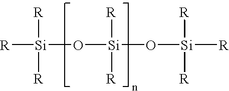

where n=0, 1, 2, 3, and R is an alkyl group. Specific examples include hexamethyl disiloxane.

Compounds other than organosilanes are also suitable, provided they contain an element Z which forms a non-volatile oxide which is a good dielectric (for example GeOₓ, AlOₓ, TiOₓ, etc.), and the rest of the molecule oxidises to form volatile compounds. The preferred compound will also preferably chemisorb or physiorb onto the anode surface to form a uniform thin film. Organotitanates, like organosilanes, are known as adhesion promoters which can form a thin film on ITO. The nature of the resulting dielectric film is obviously one of the criteria for selecting desirable compounds.

Formation of a monolayer of an organosilane on ITO is well known, and self-assembly techniques in general are well known. There are examples of the use of organosilanes in the fabrication of electroluminescent devices, for example in U.S. Pat. No. 5,677,545 a polymer with anchoring groups is deposited onto ITO so it forms an oriented layer. In JP06325345 an organosilane compound is chemically absorbed onto a cathode layer, and then the light emitting material deposited on top. In all these cases however, the organosilane compound remains in the device, and hence is a different composition and has a different purpose to that in the present invention.

Although in the above embodiment, the surface on which the dielectric material is formed is a substantially transparent electrically conductive anode comprising ITO, other materials such as tin oxide, indium oxide, zinc oxide, or zinc-doped indium oxide can be used as alternatives, if desired.

In the above embodiment, the gas used for the glow discharge was oxygen. Other oxidising media, such as for example nitrous oxide, which provide oxygen radicals in a plasma, may be used as an alternative.

1. A method of providing layer including a metal, or silicon, or germanium, and oxygen on a surface, the method comprising the steps of:
a. forming an adsorbed layer less than 12 monolayers thick on said surface by exposing said surface to a liquid or vapor comprising an organosilane or an organic compound containing germanium or a metal,
b. removing said surface that has had said adsorbed layer formed thereon from exposure to said liquid or vapor; and
c. treating said layer by exposure to an oxidizing medium, thereby converting said adsorbed layer to a layer including the metal or silicon or germanium and oxygen.

2. A method according to claim 2, wherein the organosilane satisfies the general formula
(X)₃SiR
wherein X is hydrolyzable group and R is an organic fragment.

3. A method according to claim 2, wherein X is selected from the group consisting of OEt, OMe Cl.

4. A method according to claim 2, wherein R is an alkyl group.

5. A method according to claim 1 wherein the oxidizing medium of comprises a glow discharge in a gas including oxygen radicals.

6. An electroluminescent device comprising a substrate, a cathode, a substantially transparent electrically conductive anode, and an organic light emitting layer, wherein a dielectric layer which promotes the injection of holes from the anode into the light emitting layer is provided between said anode and said light emitting layer using a method according to claim 1.

7. An electroluminescent device according to claim 6, wherein the dielectric layer has a thickness less than 2 nm.

8. A method according to claim 1, wherein said method consists of said steps.

9. A method according to claim 1, wherein said liquid or vapor consists of said organosilane or organic compound.

10. A method according to claim 3, wherein R is an alkyl group.

11. A method according to claim 1, wherein the oxidization medium consists of a glow discharge in a gas including oxygen radicals.
